(19) United States
(12) Patent Application Publication
(10) Pub. No.: US 2019/0037705 A1
(43) Pub. Date: Jan. 31, 2019

(54) COATED ELECTRICAL ASSEMBLY

(71) Applicant: SEMBLANT LIMITED, London (GB)

(72) Inventors: Shailendra Vikram SINGH, Melbourn, Hertfordshire (GB); Gianfranco ARESTA, Melbourn, Hertfordshire (GB); Andrew Simon Hall BROOKS, Melbourn, Hertfordshire (GB); Gareth HENNIGHAN, Melbourn, Hertfordshire (GB)

(21) Appl. No.: 16/071,647

(22) PCT Filed: Jan. 19, 2017
(86) PCT No.: PCT/GB2017/050125

§ 371 Date: Jul. 20, 2018

(30) Foreign Application Priority Data
Jan. 22, 2016 (GB) 1601221.3

(51) Int. Cl. H05K 3/28; H05K 1/18; B05D 1/00

(52) U.S. Cl. CPC H05K 3/285; H05K 3/284; H05K 1/181; B05D 1/62; H05K 2203/085; H05K 2203/1338; H05K 2201/0162; H05K 2203/1322; H05K 2203/122; H05K 2203/087; H05K 2203/086; H05K 2201/09872; H05K 2203/095

(57) ABSTRACT

An electrical assembly which has a multi-layer conformal coating comprising three or more layers on at least one surface of the electrical assembly, wherein the lowest layer of the multi-layer conformal coating, which is in contact with the at least one surface of the electrical assembly, is obtainable by plasma deposition of a precursor mixture comprising (a) one or more organo-silicon compounds, (b) optionally O₂, N₂O, NO₂, H₂, NH₃ and/or N₂, and (c) optionally He, Ar and/or Kr; the uppermost layer of the multi-layer conformal coating is obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr; and the multi-layer coating comprises one or more layers which is obtainable by plasma deposition of a precursor mixture comprising (a) one or more hydrocarbon compounds of formula (A), (b) optionally NH₃, N₂O, N₂, NO₂, CH₄, C₂H₆, C₃H₆ and/or C₃H₈, and (c) optionally He, Ar and/or Kr, Z₁ represents C₁-C₃ alkyl or C₂-C₃ alkenyl; Z₂ represents hydrogen, C₁-C₃ alkyl or C₂-C₃ alkenyl; Z₃ represents hydrogen, C₁-C₃ alkyl or C₂-C₃ alkenyl; Z₄ represents hydrogen, C₁-C₃ alkyl or C₂-C₃ alkenyl; Z₅ represents hydrogen, C₁-C₃ alkyl or C₂-C₃ alkenyl; and Z₆ represents hydrogen, C₁-C₃ alkyl or C₂-C₃ alkenyl.

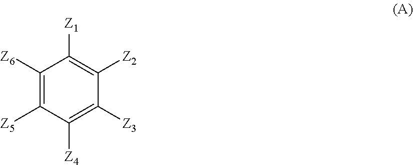

### FIELD OF THE INVENTION

The present invention relates to a coated electrical assembly and to methods of preparing a coated electrical assembly.

### BACKGROUND TO THE INVENTION

Conformal coatings have been used for many years in the electronics industry to protect electrical assemblies from environmental exposure during operation. A conformal coating is a thin and flexible layer of protective lacquer that conforms to the contours of an electrical assembly, such as a printed circuit board, and its components.

There are 5 main classes of conformal coatings, according to the IPC definitions: AR (acrylic), ER (epoxy), SR (silicones), UR (urethanes) and XY (paraxylylene). Of these 5 types, paraxylylene (or parylene) is generally accepted to offer the best chemical, electrical and physical protection. This deposition process is time consuming and expensive, and the starting material is expensive.

Plasma processed polymers/coatings have emerged as promising alternatives to conventional conformal coatings. Conformal coatings deposited by plasma deposition techniques have been described in, for example, WO 2013/132250. These coatings offer at least similar levels of chemical, electrical and physical protection as commercially available coatings such as parylene, but can be manufactured more easily and cheaply. Further, the coated electrical assemblies can be easily repaired or reworked

Despite these developments, there remains a need for improved conformal coatings that offer higher levels of robustness, by increasing adhesion between the coating and the substrate and between layers within the coating. Increased moisture protection is also desirable, so that products containing the coated electrical assemblies are waterproof. Finally, it would be advantageous to develop coatings that do not require fluorine-containing precursor materials or fluorine-containing waste materials, both of which are toxic and potentially damaging to the environment.

### SUMMARY OF THE INVENTION

The present inventors have surprisingly found that multi-layer conformal coatings which have layers of formula SiOₓH_{y}C_{z}Nₐ obtainable by plasma deposition of organosilicon compounds and hydrocarbon layer(s) of formula CₘHₙ obtainable by plasma-deposition of hydrocarbon compounds of formula (A) as herein defined provide high levels of chemical, electrical and physical protection. The excellent moisture-barrier properties of such coatings are particularly desirable, and potentially could result in coated electrical assemblies with a much higher level of waterproofing than is currently available. Further, the coatings are very robust due to good adhesion to the surface of the substrate coated and good adhesion between layers. Moreover, the precursor mixtures used in the plasma deposition process contain relatively inexpensive precursors and generally do not result in the formation of large quantities of highly toxic fluorine-containing waste materials.

Accordingly, the present invention provides an electrical assembly which has a multi-layer conformal coating comprising three or more layers on at least one surface of the electrical assembly, wherein:
the lowest layer of the multi-layer conformal coating, which is in contact with the at least one surface of the electrical assembly, is obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr;
the uppermost layer of the multi-layer conformal coating is obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr; and
the multi-layer coating comprises one or more layers which is obtainable by plasma deposition of a precursor mixture comprising (a) one or more hydrocarbon compounds of formula (A), (b) optionally NH₃, N₂O, N₂, NO₂, CH₄, C₂H₆, C₃H₆ and/or C₃H₈, and (c) optionally He, Ar and/or Kr,

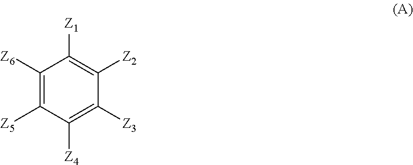

wherein:

Z₁ represents C₁-C₃ alkyl or C₂-C₃ alkenyl;

Z₂ represents hydrogen, C₁-C₃ alkyl or C₂-C₃ alkenyl;

Z₃ represents hydrogen, C₁-C₃ alkyl or C₂-C₃ alkenyl;

Z₄ represents hydrogen, C₁-C₃ alkyl or C₂-C₃ alkenyl;

Z₅ represents hydrogen, C₁-C₃ alkyl or C₂-C₃ alkenyl; and

Z₆ represents hydrogen, C₁-C₃ alkyl or C₂-C₃ alkenyl.

The invention further provides an electrical component which has a multi-layer conformal coating of the invention as herein defined on at least one surface of the electrical component.

### BRIEF DESCRIPTION OF THE FIGURES

FIG. 1 shows an example of an electrical assembly of the invention which has a multi-layer conformal coating.

FIGS. 2 to 4 show cross sections through the multi-layer conformal coating in FIG. 1, and depict the structures of preferred coatings.

FIG. 5 shows the Fourier transform infrared (FTIR) spectrum for the coating prepared in Example 1.

FIG. 6 shows the FTIR spectrum for the coating prepared in Example 2.

FIG. 7 shows the FTIR spectrum for the coating prepared in Example 3.

FIG. 8 shows the FTIR spectrum for the coating prepared in Example 4.

FIG. 9 shows the FTIR spectrum for the multi-layer conformal coating prepared in Example 5.

### DETAILED DESCRIPTION OF THE INVENTION

The multi-layer conformal coatings of the invention comprise layers of formula SiOₓH_{y}C_{z}Nₐ which are obtainable by plasma deposition of organosilicon compounds to give layers. The multi-layer conformal coatings of the invention also comprise at least one layer of formula CₘHₙ which is obtainable by plasma deposition of hydrocarbon compounds of formula (A) as herein defined.

The organosilicon compound(s) can be deposited in the presence or absence of reactive gases and/or non-reactive gases. The resulting layers deposited have general formula SiOₓH_{y}C_{z}Nₐ, wherein the values of x, y, z and a depend upon (a) the specific organosilicon compound(s) used, (b) whether or not a reactive gas is present and the identify of that reactive gas, and (c) whether or not a non-reactive gas is present, and the identify of that non-reactive gas. For example, if no nitrogen is present in the organosilicon compound(s) and a reactive gas containing nitrogen is not used, then the value of a will be 0. As will be discussed in further detail below, the values of x, y, z and a can be tuned by selecting appropriate organosilicon compound(s) and/or reactive gases, and the properties of each layer and the overall coating controlled accordingly.

For the avoidance of doubt, it will be appreciated that layers obtainable by plasma deposition of organosilicon compound(s) may have organic or inorganic character, depending upon the exact precursor mixture, despite the organic nature of the precursor mixtures used to form those layers. In an organic layer of general formula SiOₓH_{y}C_{z}Nₐ the values of y and z will be greater than zero, whereas in an inorganic layer of general formula SiOₓH_{y}C_{z}Nₐ the values of y and z will tend towards zero. The organic nature of a layer can easily be determined by a skilled person using routine analytical techniques, such as by detecting the presence of carbon-hydrogen and/or carbon-carbon bonds using spectroscopic techniques well known to those skilled in the art. For example, carbon-hydrogen bonds can be detected using Fourier transform infrared spectroscopy. Similarly, the inorganic nature of a layer can easily be determined by a skilled person using routine analytical techniques, such as by detecting the absence of carbon-hydrogen and/or carbon-carbon bonds using spectroscopic techniques well known to those skilled in the art. For example, the absence of carbon-hydrogen bonds can be assessed using Fourier transform infrared spectroscopy.

The hydrocarbon layer of formula CₘHₙ can also be deposited using compounds of formula (A) in the presence or absence of reactive gases and/or non-reactive gases. The resulting layers deposited are polymeric hydrocarbons with general formula CₘHₙ. Such polymeric hydrocarbons are organic. The CₘHₙ layer is typically an amorphous polymeric hydrocarbon with a linear, branched and/or networked chain structure. Depending on the specific precursor and co-precursor (i.e. reactive gases and/or non-reactive gases) the CₘHₙ layer may contain aromatic rings in the structure. The values of m and n, the density of the polymer and/or presence aromatic rings can be tuned by varying the applied power to generate the plasma and by varying the flow of precursor and/or of the co-precursor. For example, by increasing the power the concentration of aromatic rings can be reduced and the density of the polymer can be increased. By increasing the ratio of the flow rate of the precursors over co-precursor (i.e. reactive gases and/or non-reactive gases) the density of aromatic rings can be increased.

### Plasma Deposition Process

The layers present in the multi-layer conformal coatings of the invention are obtainable by plasma deposition, typically plasma enhanced chemical vapour deposition (PECVD) or plasma enhanced physical vapour deposition (PEPVD), preferably PECVD, of a precursor mixture. The plasma deposition process is typically carried out at a reduced pressure, typically 0.001 to 10 mbar, preferably 0.01 to 1 mbar, for example about 0.7 mbar. The deposition reactions occur in situ on the surface of the electrical assembly, or on the surface of layers that have already been deposited.

Plasma deposition is typically carried out in a reactor that generates plasma which comprises ionized and neutral feed gases/precursors, ions, electrons, atoms, radicals and/or other plasma generated neutral species. A reactor typically comprises a chamber, a vacuum system, and one or more energy sources, although any suitable type of reactor configured to generate plasma may be used. The energy source may include any suitable device configured to convert one or more gases to a plasma. Preferably the energy source comprises a heater, radio frequency (RF) generator, and/or microwave generator.

Plasma deposition results in a unique class of materials which cannot be prepared using other techniques. Plasma deposited materials have a highly disordered structure and are generally highly cross-linked, contain random branching and retain some reactive sites. These chemical and physical distinctions are well known and are described, for example in Plasma Polymer Films, Hynek Biederman, Imperial College Press 2004 and Principles of Plasma Discharges and Materials Processing, 2^{nd} Edition, Michael A. Lieberman, Alan J. Lichtenberg, Wiley 2005.

Typically, the electrical assembly is placed in the chamber of a reactor and a vacuum system is used to pump the chamber down to pressures in the range of 10⁻³ to 10 mbar. One or more gases is typically then injected (at controlled flow rate) into the chamber and an energy source generates a stable gas plasma. One or more precursor compounds is typically then be introduced, as gases and/or vapours, into the plasma phase in the chamber. Alternatively, the precursor compound may be introduced first, with the stable gas plasma generated second. When introduced into the plasma phase, the precursor compounds are typically decomposed (and/or ionized) to generate a range of active species (i.e. radicals) in the plasma that is deposited onto and forms a layer on the exposed surface of electrical assembly.

The exact nature and composition of the material deposited typically depends on one or more of the following conditions (i) the plasma gas selected; (ii) the particular precursor compound(s) used; (iii) the amount of precursor compound(s) [which may be determined by the combination of the pressure of precursor compound(s), the flow rate and the manner of gas injection]; (iv) the ratio of precursor compound(s); (v) the sequence of precursor compound(s); (vi) the plasma pressure; (vii) the plasma drive frequency; (viii) the power pulse and the pulse width timing; (ix) the coating time; (x) the plasma power (including the peak and/or average plasma power); (xi) the chamber electrode arrangement; and/or (xii) the preparation of the incoming assembly.

Typically the plasma drive frequency is 1 kHz to 4 GHz. Typically the plasma power density is 0.001 to 50 W/cm², preferably 0.01 W/cm² to 0.02 W/cm², for example about 0.0175 W/cm². Typically the mass flow rate is 5 to 1000 sccm, preferably 5 to 20 sccm, for example about 10 sccm. Typically the operating pressure is 0.001 to 10 mbar, preferably 0.01 to 1 mbar, for example about 0.7 mbar. Typically the coating time is 10 seconds to >60 minutes, for example 10 seconds to 60 minutes.

Plasma processing can be easily scaled up, by using a larger plasma chamber. However, as a skilled person will appreciate, the preferred conditions will be dependent on the size and geometry of the plasma chamber. Thus, depending on the specific plasma chamber that is being used, it may be beneficial for the skilled person to modify the operating conditions.

### Precursor Mixtures Containing One or More Organosilicon Compounds

Some layers of the multi-layer coatings described herein are formed from a precursor mixture that comprises one or more organosilicon compounds, and optionally further comprises a reactive gas (such as O₂) and/or a non-reactive gas (such as Ar). Typically the precursor mixture consists, or consists essentially, of the one or more organosilicon compounds, the optional reactive gas(es) and optional non-reactive gas(es).

This precursor mixture typically contains no, or substantially no, halogen-containing components (i.e. chlorine, fluorine, bromine and iodine are typically absent from the precursor mixture). It is preferred that halogens are absent such the coating is halogen-free and halogens are not formed as waste products during the manufacturing process, such that the coatings and their formation are environmentally friendly. As well as these advantages, the absence of halogens in any layers in the coating also improves adhesion between layers within the multi-layer coating and results in improved robustness. That is because halogen-containing, particularly fluorine-containing, layers (such as those found in the coatings described in WO 2013/132250) are generally very hydrophobic due to the electronegativity of the halogens (this is particularly notable for fluorine). Although the hydrophobicity of halogen-containing layers can impart desirable properties on multi-layer coatings, the hydrophobic nature of the layers can result in adhesion problems between layers within the multi-layer coating and a lack of robustness. By providing coatings which are halogen-free, the present invention overcomes this potential problem with halogen-containing coatings whilst retaining similar, if not greater, levels of chemical, electrical and physical protection.

The resulting layers deposited have general formula SiOₓH_{y}C_{z}Nₐ, wherein the values of x, y, z and a depend upon (i) the specific organosilicon compound(s) used, and (ii) whether or not a reactive gas is present and the identify of that reactive gas.

When the one or more organosilicon compounds are plasma deposited in the absence of an excess of oxygen and nitrogen-containing reactive gas (such as NH₃, O₂, N₂O or NO₂), the resulting layer will be organic in nature and will be of general formula SiOₓH_{y}C_{z}Nₐ. The values of y and z will be greater than 0. The values of x and a will be greater than 0 if O or N is present in the precursor mixture, either as part of the organosilicon compound(s) or as a reactive gas.

When the one or more organosilicon compounds are plasma deposited in the presence of oxygen-containing reactive gas (such as O₂ or N₂O or NO₂), the hydrocarbon moieties in the organosilicon precursor react with the oxygen-containing reactive gas to form CO₂ and H₂O. This will increase the inorganic nature of the resulting layer. If sufficient oxygen-containing reactive gas is present, all of the hydrocarbon moieties maybe removed, such that resulting layer is substantially inorganic/ceramic in nature (in which in the general formula SiOₓH_{y}C_{z}Nₐ, y, z and a will have negligible values tending to zero). The hydrogen content can be reduced further by increasing RF power density and decreasing plasma pressure, thus enhancing the oxidation process and leading to a dense inorganic layer (in which in the general formula SiOₓH_{y}C_{z}Nₐ, x is as high as 2 with y, z and a will have negligible values tending to zero).

Typically, the precursor mixture comprises one organosilicon compound, but it may be desirable under some circumstances to use two or more different organosilicon compounds, for example two, three or four different organosilicon compounds.

The organosilicon compound typically does not contain halogen atoms (i.e. chlorine, fluorine, bromine and iodine are absent from the organosilicon compound). Typically, the organosilicon compound is an organosiloxane, an organosilane, a nitrogen-containing organosilicon compound such as a silazane or an aminosilane. The organosilicon compound may be linear or cyclic.

The organosilicon compound may be a compound of formula (I):

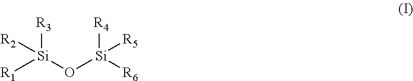

wherein each of R₁ to R₆ independently represents a C₁-C₆ alkyl group, a C₂-C₆ alkenyl group or hydrogen, provided that at least one of R₁ to R₆ does not represent hydrogen. Preferably, each of R₁ to R₆ independently represents a C₁-C₃ alkyl group, a C₂-C₄ alkenyl group or hydrogen, for example methyl, ethyl, vinyl, allyl or hydrogen, provided that at least one of R₁ to R₆ does not represent hydrogen. Preferably at least two or three, for example four, five or six, of R₁ to R₆ do not represent hydrogen. Preferred examples include hexamethyldisiloxane (HMDSO), tetramethyldisiloxane (TMDSO), 1,3-divinyltetramethyldisiloxane (DVTMDSO) and hexavinyldisiloxane (HVDSO). Hexamethyldisiloxane (HMDSO) and tetramethyldisiloxane (TMDSO) are particularly preferred, with hexamethyldisiloxane (HMDSO) most preferred.

Alternatively, the organosilicon compound may be a compound of formula (II):

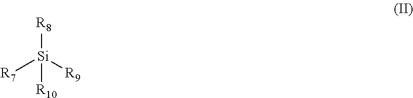

wherein each of R₇ to R₁₀ independently represents a C₁-C₆ alkyl group, a C₁-C₆ alkoxy group, a C₂-C₆ alkenyl group, hydrogen, or a —(CH₂)₁₋₄NR′R″ group in which R′ and R″ independently represent a C₁-C₆ alkyl group, provided that at least one of R₇ to R₁₀ does not represent hydrogen. Preferably each of R₇ to R₁₀ independently represents a C₁-C₃ alkyl group, C₁-C₃ alkoxy group, a C₂-C₄ alkenyl group, hydrogen or a —(CH₂)₂₋₃NR′R″ group in which R′ and R″ independently represent a methyl or ethyl group, for example methyl, ethyl, isopropyl, methoxy, ethoxy, vinyl, allyl, hydrogen or —CH₂CH₂CH₂N(CH₂CH₃)₂, provided that at least one of R₇ to R₁₀ does not represent hydrogen. Preferably at least two, for example three or four, of R₇ to R₁₀ do not represent hydrogen. Preferred examples include allyltrimethylsilane, allyltrimethoxysilane (ATMOS), tetraethylorthosilicate (TEOS), 3-(diethylamino)propyl-trimethoxysilane, trimethylsilane (TMS) and triisopropylsilane (TiPS).

Alternatively, the organosilicon compound may be a cyclic compound of formula (III):

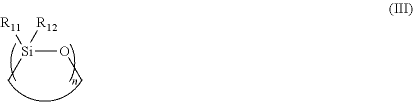

wherein n represents 3 or 4, and each of R₁₁ and R₁₂ each independently represents a C₁-C₆ alkyl group, a C₂-C₆ alkenyl group or hydrogen, provided that at least one of R₁₁ and R₁₂ does not represent hydrogen. Preferably, each of R₁₁ and R₁₂ independently represents a C₁-C₃ alkyl group, a C₂-C₄ alkenyl group or hydrogen, for example methyl, ethyl, vinyl, allyl or hydrogen, provided that at least one of R₁₁ and R₁₂ does not represent hydrogen. Preferred examples include trivinyl-trimethyl-cyclotrisiloxane (V₃D₃), tetravinyl-tetramethyl-cyclotetrasiloxane (V₄D₄), tetramethylcyclotetrasiloxane (TMCS) and octamethylcyclotetrasiloxane (OMCTS).

Alternatively, the organosilicon compound may be a compound of formula (IV):

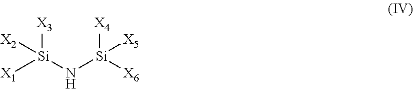

wherein each of X₁ to X₆ independently represents a C₁-C₆ alkyl group, a C₂-C₆ alkenyl group or hydrogen, provided that at least one of X₁ to X₆ does not represent hydrogen. Preferably each of X₁ to X₆ independently represents a C₁-C₃ alkyl group, a C₂-C₄ alkenyl group or hydrogen, for example methyl, ethyl, vinyl, allyl or hydrogen, provided that at least one of X₁ to X₆ does not represent hydrogen. Preferably at least two or three, for example four, five or six, of X₁ to X₆ do not represent hydrogen. A preferred example is hexamethyldisilazane (HMDSN).

Alternatively, the organosilicon compound may be a cyclic compound of formula (V):

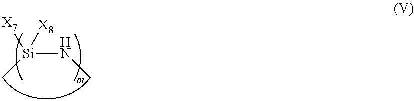

wherein m represents 3 or 4, and each of X₇ and X₈ independently represents a C₁-C₆ alkyl group, a C₂-C₆ alkenyl group or hydrogen, provided that at least one of X₇ and X₈ does not represent hydrogen. Preferably, each of X₇ and X₈ independently represents a C₁-C₃ alkyl group, a C₂-C₄ alkenyl group or hydrogen, for example methyl, ethyl, vinyl, allyl or hydrogen, provided that at least one of X₇ and X₈ does not represent hydrogen. A preferred example is 2,4,6-trimethyl-2,4,6-trivinylcyclotrisilazane.

Alternatively, the organosilicon compound may be a compound of formula (VI):

Hₐ(X⁹)_{b}Si(N(X¹⁰)₂)_{4-a-b} (VI)

wherein X⁹ and X¹⁰ independently represent C₁-C₆ alkyl groups, a represents 0, 1 or 2, b represents 1, 2 or 3, and the sum of a and b is 1, 2 or 3. Typically, X⁹ and X¹⁰ represent a C₁-C₃ alkyl group, for example methyl or ethyl. Preferred examples are dimethylamino-trimethylsilane (DMATMS), bis(dimethylamino)dimethylsilane (BDMADMS) and tris(dimethylamino)methylsilane (TDMAMS).

Preferably the organosilicon compound is hexamethyldisiloxane (HMDSO), tetramethyldisiloxane (TMDSO), 1,3-divinyltetramethyldisiloxane (DVTMDSO), hexavinyldisiloxane (HVDSO allyltrimethylsilane, allyltrimethoxysilane (ATMOS), tetraethylorthosilicate (TEOS), 3-(diethylamino)propyl-trimethoxysilane, trimethylsilane (TMS), triisopropylsilane (TiPS), trivinyl-trimethyl-cyclotrisiloxane (V₃D₃), tetravinyl-tetramethyl-cyclotetrasiloxane (V₄D₄), tetramethylcyclotetrasiloxane (TMCS), octamethylcyclotetrasiloxane (OMCTS), hexamethyldisilazane (HMDSN), 2,4,6-trimethyl-2,4,6-trivinylcyclotrisilazane, dimethylamino-trimethylsilane (DMATMS), bis(dimethylamino)dimethylsilane (BDMADMS), or tris(dimethylamino)methylsilane (TDMAMS). Hexamethyldisiloxane (HMDSO) and tetramethyldisiloxane (TMDSO) are particularly preferred, with hexamethyldisiloxane (HMDSO) most preferred.

The precursor mixture containing one or more organosilicon compounds optionally further comprises reactive gas(es). The reactive gas is selected from O₂, N₂O, NO₂, H₂, NH₃, and/or N₂. These reactive gases are generally involved chemically in the plasma deposition mechanism, and so can be considered to be co-precursors.

O₂, N₂O and NO₂ are oxygen-containing co-precursors, and are typically added in order to increase the inorganic character of the resulting layer deposited. This process is discussed above. N₂O and NO₂ are also nitrogen-containing co-precursors, and are typically added in order to increase additionally the nitrogen content of the resulting layer deposited (and consequently the value of a in the general formula SiOₓH_{y}C_{z}Nₐ is increased).

H₂ is a reducing co-precursor, and is typically added in order to reduce the oxygen content (and consequently the value of x in the general formula SiOₓH_{y}C_{z}Nₐ) of the resulting layer deposited. Under such reducing conditions, the carbon and hydrogen are also generally removed from the resulting layer deposited (and consequently the values of y and z in the general formula SiOₓH_{y}C_{z}Nₐ are also reduced). Addition of H₂ as a co-precursor increases the level of cross-linking in the resulting layer deposited.

N₂ is a nitrogen-containing co-precursor, and is typically added in order to increase the nitrogen content of the resulting layer deposited (and consequently the value of a in the general formula SiOₓH_{y}C_{z}Nₐ is increased).

NH₃ is also a nitrogen-containing co-precursor, and so is typically added in order to increase the nitrogen content of the resulting layer deposited (and consequently the value of a in the general formula SiOₓH_{y}C_{z}Nₐ is increased). However, NH₃ additionally has reducing properties. As with the addition of H₂, this means that when NH₃ is used as a co-precursor, oxygen, carbon and hydrogen are generally removed from the resulting layer deposited (and consequently the values of x, y and z in the general formula SiOₓH_{y}C_{z}Nₐ are reduced). Addition of NH₃ as a co-precursor increases the level of cross-linking in the resulting layer deposited. The resulting layer tends towards a silicon nitride structure.

A skilled person can easily adjust the ratio of reactive gas to organosilicon compound(s) at any applied power density, in order to achieve the desired modification of the resulting layer deposited.

The precursor mixture also optionally further comprises non-reactive gas(es). The non-reactive gas is He, Ar or Kr. The non-reactive gas is not involved chemically in the plasma deposition mechanism, but does generally influence the physical properties of the resulting material. For example, addition of He, Ar or Kr will generally increase the density of the resulting layer, and thus its hardness. Addition of He, Ar or Kr also increases cross-linking of the resulting deposited material.

### Precursor Mixtures Containing One or More Hydrocarbon Compounds of Formula (A)

Some layers of the multi-layer coatings described herein are hydrocarbon polymer of formula CₘHₙ formed from a precursor mixture that comprises one or more hydrocarbon compounds of formula (A), and optionally further comprises a reactive gas (such as NH₃) and/or a non-reactive gas (such as Ar). Typically the precursor mixture consists, or consists essentially, of the one or more hydrocarbon compounds of formula (A), the optional reactive gas(es) and optional non-reactive gas(es).

This precursor mixture typically contains no, or substantially no, halogen-containing components (i.e. chlorine, fluorine, bromine and iodine are typically absent from the precursor mixture). It is preferred that halogens are absent such the coating is halogen-free and halogens are not formed as waste products during the manufacturing process, such that the coatings and their formation are environmentally friendly.

Hydrocarbon compounds of formula (A) have the following structure:

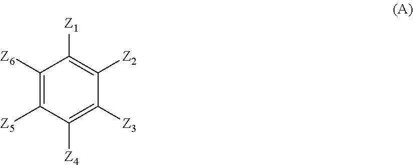

wherein Z₁ represents C₁-C₃ alkyl or C₂-C₃ alkenyl; Z₂ represents hydrogen, C₁-C₃ alkyl or C₂-C₃ alkenyl; Z₃ represents hydrogen, C₁-C₃ alkyl or C₂-C₃ alkenyl; Z₄ represents hydrogen, C₁-C₃ alkyl or C₂-C₃ alkenyl; Z₅ represents hydrogen, C₁-C₃ alkyl or C₂-C₃ alkenyl; and Z₆ represents hydrogen, C₁-C₃ alkyl or C₂-C₃ alkenyl.

Typically, Z₁ represents methyl, ethyl, or vinyl. Typically, Z₂ represents hydrogen, methyl, ethyl, or vinyl. Typically, Z₃ represents hydrogen, methyl, ethyl or vinyl. Typically, Z₄ represents hydrogen, methyl, ethyl or vinyl. Typically, Z₅ represents hydrogen, methyl, ethyl or vinyl, preferably hydrogen. Typically, Z₆ represents hydrogen, methyl, ethyl or vinyl, preferably hydrogen.

Preferably, Z₅ and Z₆ represent hydrogen.

More preferably, Z₁ represents methyl, ethyl or vinyl, Z₂ represents hydrogen, methyl, ethyl or vinyl, Z₃ represents hydrogen, methyl, ethyl or vinyl, Z₄ represents hydrogen, methyl, ethyl or vinyl, Z₅ represents hydrogen and Z₆ represents hydrogen.

It is generally preferred that two of Z₂ to Z₄ represent hydrogen.

Preferred hydrocarbon compounds of formula (A) are 1,4-dimethylbenzene, 1,3-dimethylbenzene, 1,2-dimethylbenzene, toluene, 4-methyl styrene, 3-methyl styrene, 2-methyl styrene, 1,4-divinyl benzene, 1,3-divinyl benzene, 1,2-divinyl benzene, 1,4-ethylvinylbenzene, 1,3-ethylvinylbenze and 1,2-ethylvinylbenzene.

1,4-dimethylbenzene is particularly preferred.

Divinyl benzenes are also particularly preferred, and are typically used in the form of a mixture of 1,4-divinyl benzene, 1,3-divinyl benzene and 1,2-divinyl benzene.

The precursor mixture containing one or more hydrocarbon compounds of formula (A) optionally further comprises reactive gas(es). The reactive gas is selected from N₂O, NO₂, NH₃, N₂, CH₄, C₂H₆, C₃H₆ and/or C₃H₈. These reactive gases are generally involved chemically in the plasma deposition mechanism, and so can be considered to be co-precursors.

A skilled person can easily adjust the ratio of reactive gas to compound(s) of formula (A) at any applied power density, in order to achieve the desired modification of the resulting layer deposited.

The precursor mixture containing one or more hydrocarbon compounds of formula (A) also optionally further comprises non-reactive gas(es). The non-reactive gas is He, Ar or Kr, with He and Ar preferred. The non-reactive gas is not involved chemically in the plasma deposition mechanism, but does generally influence the physical properties of the resulting material. For example, addition of He, Ar or Kr will generally increase the density of the resulting layer, and thus its hardness. Addition of He, Ar or Kr also increases cross-linking of the resulting deposited material.

Structure and Properties of the Multi-Layer Conformal Coating

The multi-layer conformal coating of the invention comprises at least three layers. The first, or lowest layer, in the multi-layer coating is in contact with the surface of the electrical assembly. The final, or uppermost layer, in the multi-layer coating is in contact with the environment. The third and each optional subsequent layer is located between the first/lowest and final/uppermost layers.

Typically, the multi-layer coating comprises from three to thirteen layers, preferably three to eleven layers or five to nine layers. Thus, the multi-layer coating may have three, four, five, six, seven, eight, nine, ten, eleven, twelve or thirteen layers.

Typically every layer in the multi-layer coating is either:
[i] obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr; or
[ii] obtainable by plasma deposition of a precursor mixture comprising (a) one or more compounds of formula (A), (b) optionally NH₃, N₂O, N₂, NO₂, CH₄, C₂H₆, C₃H₆ and/or C₃H₈, and (c) optionally He, Ar and/or Kr.

Preferably, the multi-layer coating has an odd number of layers which alternate between layers of type [i] and layers of type [ii]. The layers of type [i] will be the lowest and uppermost layers. Thus, preferred coatings have the structure [i][ii][i] (for a three layer coating), [i][ii][i][ii][i] (for a five layer coating), [i][ii][i][ii][i][ii][i] (for a seven layer coating), [i][ii][i][ii][i][ii][i][ii][i] (for a nine layer coating) and so on. As will be appreciated from the discussion below of preferred properties for each layer, each layer of type [i] can be the same or different and each layer of type [ii] can be the same or different.

The boundary between each layer may be discrete or graded. Thus, all of the boundaries may be discrete, or all of the boundaries may be graded, or there may be both discrete and graded boundaries with the multi-layer coating.

A graded boundary between two layers can be achieved by switching gradually over time during the plasma deposition process from the precursor mixture required to form the first of the two layers to the precursor mixture required to form the second of the two layers. The thickness of the graded region between the two layers can be adjusted by altering the time period over which the switch from the first precursor mixture to the second precursor mixture occurs. Under some circumstances graded boundaries can be advantageous, as the adhesion between layers is generally increased by a graded boundary.

A discrete boundary between two layers can be achieved by switching immediately during the plasma deposition process from the precursor mixture required to form the first of the two layers to the precursor mixture required to form the second of the two layers.

Different layers are deposited by varying the precursor mixture and/or the plasma deposition conditions in order to obtain layers which have the desired properties. The properties of each individual layer are selected such that the resulting multi-layer coating has the desired properties.

Generally, all layers of the multi-layer coatings of the invention are of type [i] or type [ii] identified above. Thus, the multi-layer coatings of the invention preferably do not contain other layers which are not obtainable by plasma deposition of precursor mixtures as herein defined. It is further preferred that all layers of the multi-layer coatings of the invention are organic, as discussed in further detail below.

### Properties of First/Lowest Layer

It is generally desirable for the multi-layer conformal coating to show good adhesion, both to the surface of the electrical assembly and between layers within the multi-layer conformal coating. This is desirable so that the multi-layer conformal coating is robust during use. Adhesion can be tested using tests known to those skilled in the art, such as a Scotch tape test or a scratch adhesion test.

The first/lowest layer of the multi-layer conformal coating, which is in contact with the at least one surface of the electrical assembly, is obtainable by plasma deposition of a precursor mixture comprising (a) one or more organosilicon compounds, (b) optionally O₂, N₂O, NO₂, H₂, NH₃ and/or N_{2,} and (c) optionally He, Ar and/or Kr. The precursor mixture typically consists, consists essentially, of these components.

It is preferable that the first/lowest layer of the multi-layer conformal coating is formed from a precursor mixture that results in a layer that adheres well to the surface of the electrical assembly. The exact precursor mixture that is required will depend upon the specific surface of the electrical assembly, and a skilled person will be able to adjust the precursor mixture accordingly. However, Si-based layers which are organic in character adhere best to the surface of the electrical assembly. Typically, therefore, the first/lowest layer of the multi-layer conformal coating is organic.

A Si-based layer with organic character, and which will have particular good adhesion to the substrate and to the next layer in the multi-layer coating, can be achieved by using a precursor mixture that contains no, or substantially no, oxygen-containing reactive gas (i.e. no, or substantially no, or O₂, N₂O or NO₂), and preferably also contains H₂, NH₃, N₂, Ar, He and/or Kr. It is thus preferable that the first/lowest layer of the multi-layer conformal coating is deposited using a precursor mixture that contains no, or substantially no, O₂, N₂O or NO₂, and more preferably additionally contains H₂, NH₃, N_{2,} Ar, He and/or Kr. The precursor mixture most preferably consists, consists essentially, of these components. The resulting coating will be organic in character and so will adhere well to the surface of the electrical assembly.

It is also generally desirable for the first/lowest layer of the multi-layer conformal coating to be capable of absorbing any residual moisture present on the substrate of the electrical assembly prior to deposition of the coating. The first/lowest layer will then generally retain the residual moisture within the coating, and thereby reduce the nucleation of corrosion and erosion sites on the substrate.

### Properties of the Final/Uppermost Layer

The final/uppermost layer of the multi-layer conformal coating, that is to say the layer that is exposed to the environment, is obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr. The precursor mixture typically consists, consists essentially, of these components.

It is generally desirable for the final/uppermost layer of the multi-layer coating to be hydrophobic. Hydrophobicity can be determined by measuring the water contact angle (WCA) using standard techniques. Typically, the WCA of the final/uppermost layer of the multi-layer coating is >90°, preferably from 95° to 115°, more preferably from 100° to 110°.

The hydrophobicity of a layer can be modified by adjusting the precursor mixture. For example, a layer which has organic character will generally be hydrophobic. Typically, therefore, the final/uppermost layer of the multi-layer conformal coating is organic. A layer with organic character can be achieved, for example, by using a precursor mixture that contains no, or substantially no, oxygen-containing reactive gas (i.e. no, or substantially no, or O₂, N₂O or NO₂). As discussed above, if an oxygen-containing gas is present in the precursor mixture, the organic character and thus hydrophobicity of the resulting layer will be reduced. It is thus preferable that the final/uppermost layer of the multi-layer conformal coating is deposited using a precursor mixture that contains no, or substantially no, O₂, N₂O or NO₂.

It is also generally desirable for the final/uppermost layer of the multi-layer conformal coating to have a hardness of at least 0.5 GPa, preferably at least 2 GPa, more preferably at least 4 GPa. The hardness is typically no greater than 11 GPa. Hardness can be measured by nanohardness tester techniques known to those skilled in the art. The hardness of a layer can be modified by adjusting the precursor mixture, for example to include a non-reactive gas such as He, Ar and/or Kr. This results in a layer which is denser and thus harder. It is thus preferably that the final/uppermost layer of the multi-layer conformal coating is deposited using a precursor mixture that comprises He, Ar and/or Kr. It is also desirable that the coating is wear resistant.

It is also possible to adjust the hardness by modifying the plasma deposition conditions. Thus, reducing the pressure at which deposition occurs generally results in a layer which is denser and thus harder. Increasing the RF power generally results in a layer which is denser and thus harder. These conditions and/or the precursor mixture can be readily adjusted to achieve a hardness of at least 0.5 GPa.

It is also generally desirable for the final/uppermost layer of the multi-layer conformal coating to be oleophobic. Generally, a layer that is hydrophobic will also be oloephobic. Thus, if the water contact angle (WCA) of the final/uppermost layer of the multi-layer coating is greater than 100°, then the coating will be oleophobic. A WCA of greater than 105° is preferred for increased oleophobic properties.

In view of the above, it is particularly preferred that final/uppermost layer of the multi-layer conformal coating has (a) a WCA of from 90° to 120°, preferably from 95° to 115°, more preferably from 100° to 110°, and (b) a hardness of at least 0.5 GPa.

Overall, it is particularly preferred that the final/uppermost layer of the multi-layer conformal coating is deposited using a precursor mixture that (a) contains no, or substantially no, O₂, N₂O or NO₂, and (b) comprises He, Ar and/or Kr. The precursor mixture typically consists, consists essentially, of these components.

Although it is generally preferred that the final/uppermost layer of the multi-layer conformal coating is hydrophobic, it can also be desirable for the final/uppermost layer to have both hydrophobic and hydrophilic regions. These hydrophobic and hydrophilic regions can be deposited such that channels are formed on the final/uppermost layer that guide moisture away from, for example, moisture-sensitive components.

Properties of Layers from Hydrocarbon Compounds of Formula (A)

The multi-layer conformal coatings of the invention have at least one layer which is a hydrocarbon polymer of formula CₘHₙ obtainable by plasma deposition of a precursor mixture comprising (a) one or more hydrocarbon compounds of formula (A), (b) optionally NH₃, N₂O, N₂, NO₂, CH₄, C₂H₆ C₃H₆ and/or C₃H₈, and (c) optionally He, Ar and/or Kr. The precursor mixture typically consists, consists essentially, of these components.

Typically, the multi-layer coating has one to six, preferably two to five, for example three or four layers, each of which is obtainable by plasma deposition of a precursor mixture comprising a hydrocarbon compound of formula (A).

Where more than one such layer is present, the same hydrocarbon compound(s) of formula (A) can be used for each layer or different hydrocarbon compounds of formula (A) can be used.

### Moisture Barrier Properties

It is desirable for the multi-layer conformal coating to act as a moisture barrier, so that moisture, typically in the form or water vapour, cannot breach the multi-layer conformal coating and damage the underlying electrical assembly. The moisture barrier properties of the multi-layer conformal coating can be assessed by measuring the water vapour transmission rate (WVTR) using standard techniques, such as a MOCON test. Typically, the WVTR of the multi-layer conformal coating is from 10 g/m²/day down to 0.001 g/m²/day.

Typically, the moisture barrier properties of the multi-layer conformal coating may be enhanced by inclusion of at least one layer which has a WVTR of from 0.5 g/m²/day down to 0.1 g/m²/day. This moisture barrier layer is typically not the first/lowest or final/uppermost layer of the multi-layer conformal coating. Several moisture barrier layers may be present in a multi-layer coating, each of which may have the same or different composition.

Generally, layers formed from hydrocarbon compound(s) of formula (A) as described herein form very effective moisture barriers. It is thus generally preferred that the moisture barrier properties of the multi-layer coatings of the invention are provided by layers formed from hydrocarbon compound(s) of formula (A) as described herein, and that the multi-layer coatings do not contain any inorganic layers obtainable by plasma deposition of organosilicon compounds.

Accordingly, it is preferred that all layers in the multi-layer coating obtainable by plasma deposition of organosilicon compounds (type [i] described above) are organic. It is a surprising of the present invention that such multi-layer coatings, which do not have any inorganic layers, demonstrate good moisture barrier properties, because it had previously been believed that such inorganic layers were important for achieving acceptable levels of moisture resistance. Without wishing to be bound by theory, the present inventors consider that one reason for this surprising finding is that inorganic layers often contain more defects than organic layers, and due to the surface energy of the organic layers any defects present tend not to cause a problem with regard to moisture resistance. It is believed that this property may allow for the organic layers within the multi-layer coatings of the invention to provide the required moisture barrier properties.

Further, omission of inorganic layers, such that all of the layers are organic, is advantageous, because it results in improved adhesion between layers in the multi-layer coating and leads to increased robustness. The present inventors believe that the plasma process generally results in good adhesion between organic layers. A further advantage of organic layers over inorganic layers is that organic layers are less brittle than inorganic layers, which means that coatings which do not have any inorganic layers are less likely to crack during normal handling.

Despite the preference for omitting inorganic layers, in some instances it may nevertheless be desirable to have an inorganic layers obtainable by plasma deposition of organosilicon compounds. That is because layers formed from organosilicon compounds and which are substantially inorganic in character and contain very little carbon are also very effective moisture barriers. Such layers can be obtained by, for example, plasma deposition of a precursor mixture that comprises an organosilicon compound and an oxygen-containing reactive gas (ie. O₂, N₂O or NO₂). Addition of a non-reactive gases such as He, Ar or Kr, use of a high RF power density and/or reducing the plasma pressure will also assist in forming a layer with good moisture barrier properties.

It is therefore preferred that at least one layer of the multi-layer conformal coating is obtainable by plasma deposition of a precursor mixture comprising an organosilicon compound and O₂, N₂O and/or NO₂, and preferably also He, Ar and/or Kr. Preferably the precursor mixture consists, or consists essentially, of these components.

A layer containing nitrogen atoms will also typically have desirable moisture barrier properties. Such a layer can be obtained by using a nitrogen-containing organosilicon compound, typically a silazane or aminosilane precursor, such as the compounds of formula (IV) to (VI) defined above. Nitrogen atoms can also be introduced by including N₂, NO₂, N₂O or NH₃ as a reactive gas in the precursor mixture.

It is therefore also preferred that at least one layer of the multi-layer conformal coating is obtainable by plasma deposition of a precursor mixture comprising a nitrogen-containing organosilicon compound. Alternatively, the least one layer of the multi-layer conformal coating is obtainable by plasma deposition of a precursor mixture comprising an organosilicon compound (which may or may not be a nitrogen-containing organosilicon compound) and N₂, NO₂, N₂O and/or NH₃. In both cases, the precursor mixture preferably consists, or consists essentially, of these components.

### Other Properties

The multi-layer conformal coatings are generally anti-corrosive and chemically stable, and thus resistant to immersion in, for example, acid or base or solvents such as acetone or isopropyl alcohol (IPA).

The thickness of the multi-layer conformal coating of the present invention will depend upon the number of layers that are deposited, and the thickness of each layer deposited.

Typically, the thickness of each layer is from 20 nm to 500 nm. The overall thickness of the multi-layer conformal coating is of course dependent on the number of layers, but is typically less than 5000 nm, and preferably 1000 nm to 3000 nm.

The thickness of each layer can be easily controlled by a skilled person. Plasma processes deposit a material at a uniform rate for a given set of conditions, and thus the thickness of a layer is proportional to the deposition time. Accordingly, once the rate of deposition has been determined, a layer with a specific thickness can be deposited by controlling the duration of deposition.

The thickness of the multi-layer conformal coating and each constituent layer may be substantially uniform or may vary from point to point, but is preferably substantially uniform.

Thickness may be measured using techniques known to those skilled in the art, such as a profilometry, reflectometry or spectroscopic ellipsometry.

Adhesion between layers of the multi-layer conformal coating can be improved, where necessary, by introducing a graded boundary between layers, as discussed above.

Alternatively, where necessary, discrete layers within the multi-layer conformal coating can be chosen such that they adhere well to the adjacent layers within the multi-layer conformal coating.

### The Electrical Assembly

An electrical assembly used in the present invention typically comprises a substrate comprising an insulating material, a plurality of conductive tracks present on at least one surface of the substrate, and at least one electrical component connected to at least one conductive track. The conformal coating preferably covers the plurality of conductive tracks, the at least one electrical component and the surface of the substrate on which the plurality of conductive tracks and the at least one electrical component are located. Alternatively, the coating may cover one or more electrical components, typically expensive electrical components in the PCB, whilst other parts of the electrical assembly are uncovered.

A conductive track typically comprises any suitable electrically conductive material. Preferably, a conductive track comprises gold, tungsten, copper, silver, aluminium, doped regions of semi-conductor substrates, conductive polymers and/or conductive inks. More preferably, a conductive track comprises gold, tungsten, copper, silver or aluminium.

Suitable shapes and configurations for the conductive tracks can be selected by a person skilled in the art for the particular assembly in question. Typically, a conductive track is attached to the surface of the substrate along its entire length. Alternatively, a conductive track may be attached to the substrate at two or more points. For example, a conductive track may be a wire attached to the substrate at two or more points, but not along its entire length.

A conductive track is typically formed on a substrate using any suitable method known to those skilled in the art. In a preferred method, conductive tracks are formed on a substrate using a “subtractive” technique. Typically in this method, a layer of metal (e.g., copper foil, aluminium foil, etc.) is bonded to a surface of the substrate and then the unwanted portions of the metal layer are removed, leaving the desired conductive tracks. The unwanted portions of the metal layer are typically removed from the substrate by chemical etching or photo-etching or milling. In an alternative preferred method, conductive tracks are formed on the substrate using an “additive” technique such as, for example, electroplating, deposition using a reverse mask, and/or any geometrically controlled deposition process. Alternatively, the substrate may be a silicon die or wafer, which typically has doped regions as the conductive tracks.

The substrate typically comprises any suitable insulating material that prevents the substrate from shorting the circuit of electrical assembly. The substrate preferably comprises an epoxy laminate material, a synthetic resin bonded paper, an epoxy resin bonded glass fabric (ERBGH), a composite epoxy material (CEM), PTFE (Teflon), or other polymer materials, phenolic cotton paper, silicon, glass, ceramic, paper, cardboard, natural and/or synthetic wood based materials, and/or other suitable textiles. The substrate optionally further comprises a flame retardant material, typically Flame Retardant 2 (FR-2) and/or Flame Retardant 4 (FR-4). The substrate may comprise a single layer of an insulating material or multiple layers of the same or different insulating materials. The substrate may be the board of a printed circuit board (PCB) made of any one of the materials listed above.

An electrical component may be any suitable circuit element of an electrical assembly. Preferably, an electrical component is a resistor, capacitor, transistor, diode, amplifier, relay, transformer, battery, fuse, integrated circuit, switch, LED, LED display, Piezo element, optoelectronic component, antenna or oscillator. Any suitable number and/or combination of electrical components may be connected to the electrical assembly.

The electrical component is preferably connected to an electrically conductive track via a bond. The bond is preferably a solder joint, a weld joint, a wire-bond joint, a conductive adhesive joint, a crimp connection, or a press-fit joint. Suitable soldering, welding, wire-bonding, conductive-adhesive and press-fit techniques are known to those skilled in the art, for forming the bond. More preferably the bond is a solder joint, a weld joint or a wire-bond joint, with a solder joint most preferred.

### Definitions

As used herein, the term C₁-C₆ alkyl embraces a linear or branched hydrocarbon groups having 1 to 6, preferably 1 to 3 carbon atoms. Examples include methyl, ethyl, n-propyl and i-propyl, butyl, pentyl and hexyl. As used herein, the term C₁-C₃ alkyl embraces a linear or branched hydrocarbon group having 1 to 3, preferably 1 to 2 carbon atoms. Examples include methyl, ethyl, n-propyl and i-propyl.

As used herein, the term C₂-C₆ alkenyl embraces a linear or branched hydrocarbon groups having 2 or 6 carbon atoms, preferably 2 to 4 carbon atoms, and a carbon-carbon double bond. Preferred examples include vinyl and allyl. As used herein, the term C₂-C₃ alkenyl embraces a linear or branched hydrocarbon group having 2 or 3 carbon atoms and a carbon-carbon double bond. A preferred example is vinyl.

As used herein, the term C₁-C₆ alkoxy group is a said alkyl group which is attached to an oxygen atom. Preferred examples include methoxy, ethoxy, propoxy, isopropoxy, butoxy, isobutoxy, tert-butoxy, pentoxy and hexoxy.

As used herein, the term “consists essentially of” refers to a precursor mixture comprising the components of which it consists essentially as well as other components, provided that the other components do not materially affect the essential characteristics of the resulting layer formed from the precursor mixture. Typically, a precursor mixture consisting essentially of certain components will contain greater than or equal to 95 wt % of those components, preferably greater than or equal to 99 wt % of those components.

As used herein, therefore a precursor mixture that contains “substantially no” specified component(s) contains less than 5 wt % of the specified component(s), preferably less than 1 wt % of the specified component(s), most preferably less than 0.1 wt % of the specified component(s).

### DETAILED DESCRIPTION OF THE FIGURES

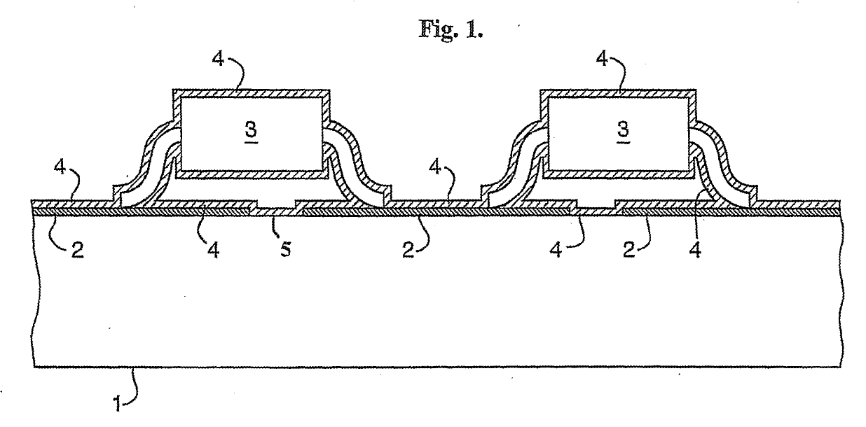

Aspects of the invention will now be described with reference to the embodiment shown in FIGS. 1 to 4, in which like reference numerals refer to the same or similar components.

FIG. 1 shows an example of an electrical assembly of the invention. The electrical assembly comprises a substrate 1 comprising an insulating material, a plurality of conductive tracks 2 present on least one surface of the substrate 1, and at least one electrical component 3 connected to at least one conductive track 2. The multi-layer conformal coating 4 covers the plurality of conductive tracks 2, the at least one electrical component 3 and the surface 5 of the substrate 1 on which the plurality of conductive tracks and the at least one electrical component are located.

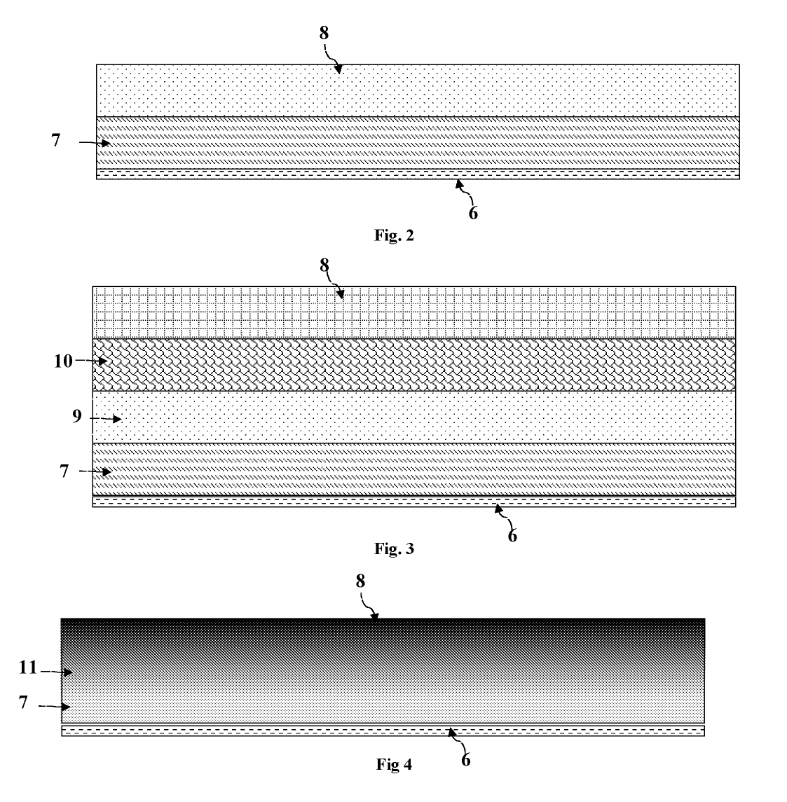

FIG. 2 shows a cross section through a preferred example of the multi-layer conformal coating 4 in FIG. 1. The multi-layer conformal coating comprises a first/lowest layer 7 which is in contact with the at least one surface 6 of the electrical assembly, and a final/uppermost layer 8. This multi-layer conformal coating has two layers, and the boundary between the layers is discrete.

FIG. 3 shows a cross section through another preferred example of the multi-layer conformal coating 4 in FIG. 1. The multi-layer conformal coating comprises a first/lowest layer 7 which is in contact with the at least one surface 6 of the electrical assembly, and a final/uppermost layer 8. Between layers 7 and 8 are two further layers 9 and 10. This multi-layer conformal coating has four layers, and the boundary between the layers is discrete.

FIG. 4 shows a cross section through another preferred example of the multi-layer conformal coating 4 in FIG. 1. The multi-layer conformal coating comprises a first/lowest layer 7 which is in contact with the at least one surface 6 of the electrical assembly, and a final/uppermost layer 8. This multi-layer conformal coating has two layers, and the boundary 11 between the layers is graded.

### EXAMPLES

Aspects of the invention will now be described with reference to the Examples below.

### Example 1

### Deposition of a Single SiOₓC_{y}H_{z} Layer Using Ar as Non-Reactive Gas

An electrical assembly was placed into a plasma-enhanced chemical vapour deposition (PECVD) deposition chamber, and the pressure was then brought to ˜10⁻² mbar. Hexamethyldisiloxane (HMDSO) and Ar were injected at a flow rate of 17.5 sccm and 20 sccm respectively. Pressure was allowed to stabilize and plasma was ignited at a RF power density of 0.057 Wcm⁻², resulting in a process pressure of 0.140 mbar. The process was run for 10 minutes.

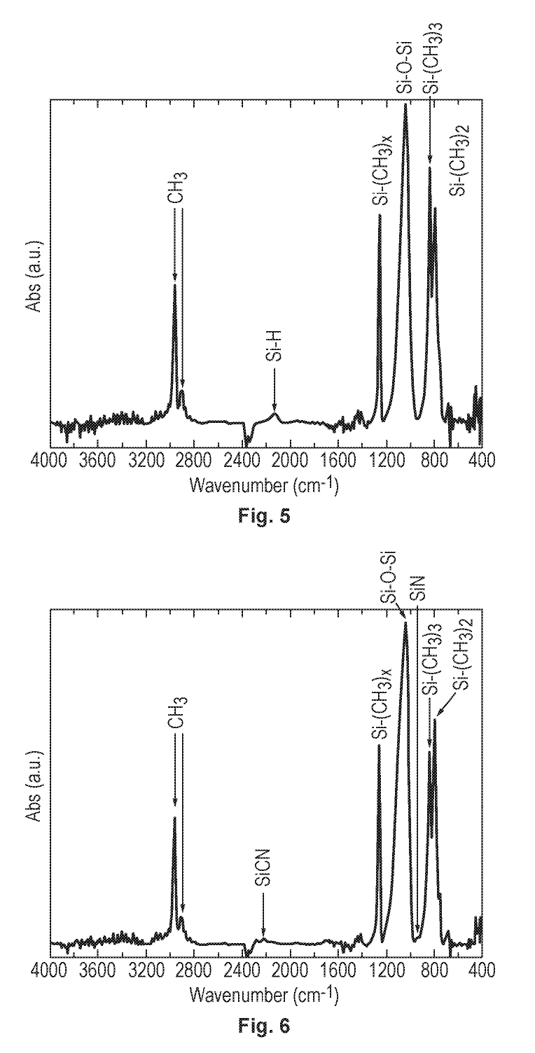

Polymeric organosilicon SiOₓC_{y}H_{z} layers were obtained on the electrical assembly. The FTIR transmission spectrum for the deposited layer is shown in FIG. 5.

The SiOₓC_{y}H_{z} layers showed hydrophobic character with a WCA (water contact angle) of ˜100°.

Coating adhesion to electrical assembly was tested on a PCB substrate by means of tape peel test resulting in coating good adhesion on both solder mask and metal substrate surfaces (i.e. no coating peeled off the solder mask and metal surfaces).

### Example 2

### Deposition of Single SiOₓC_{y}H_{z}Nₐ Layer Using N₂O as Reactive Gas

An electrical assembly was placed into a PECVD deposition chamber, and the pressure was then brought to ˜10⁻² mbar. HMDSO and N₂O were injected at a flow rate of 17.5 sccm and 30 sccm respectively. Pressure was allowed to stabilize and plasma was ignited at a RF power density of 0.057 Wcm⁻², resulting in a process pressure of 0.160 mbar. The process was run for 10 minutes.

Polymeric organosilicon SiOₓC_{y}H_{z}Nₐ layers were obtained on the electrical assembly. The FTIR transmission spectrum for the deposited layer is shown in FIG. 6.

The SiOₓC_{y}H_{z} layers showed hydrophobic character with a WCA (water contact angle) of ˜95°.

### Example 3

### Deposition of Single SiOₓC_{y}H_{z}Nₐ Layer Using NH₃ as Reactive Gas and Ar as Non-Reactive Gas

An electrical assembly was placed into a PECVD deposition chamber, and the pressure was then brought to ˜10⁻² mbar. HMDSO, NH₃ and Ar were injected at a flow rate of 4.4 sccm, 80 sccm and 20 sccm respectively. Pressure was allowed to stabilize and plasma was ignited at a RF power density of 0.057 Wcm⁻², resulting in a process pressure of 0.120 mbar. The process was run for 30 minutes.

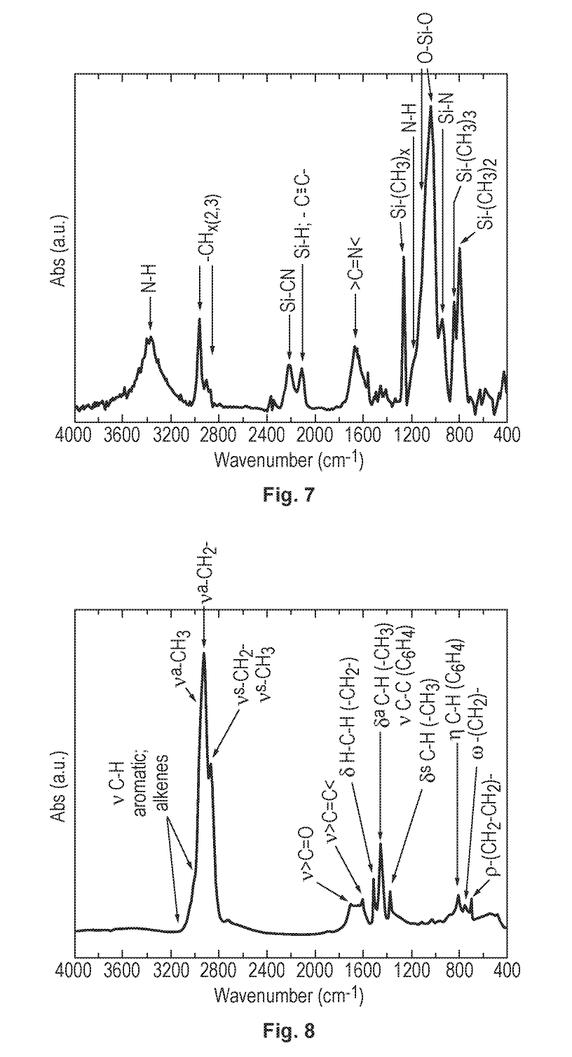

Polymeric organosilicon SiOₓC_{y}H_{z}Nₐ layers were obtained on the electrical assembly. The FTIR transmission spectrum for the deposited layer is shown in FIG. 7.

### Example 4

### Deposition of Single Hydrocarbon Layer

An electrical assembly was placed into a PECVD deposition chamber, and the pressure was then brought to ˜10⁻² mbar. 1,4-dimethylbenzene (p-Xylene) was injected at a flow rate of 85 sccm. Pressure was allowed to stabilize and plasma was ignited at a RF power density of 0.057 Wcm⁻², resulting in a process pressure of 0.048 mbar. The process was run for 20 minutes.

Polymeric CₘHₙ layers were obtained on the electrical assembly. The FTIR transmission spectrum for the deposited layer is shown in FIG. 8.

### Example 5

### Deposition of Organosilicon-Hydrocarbon Multi-Layer Conformal Coating

An organosilicon-hydrocarbon multi-layer conformal coating was deposited with the following types of layer:
1) Base-adhesion layer and Top layer: 150 nm (±10%) of SiOₓC_{y}H_{z} prepared according to Example 1.
2) Interlayer 1: 250 nm (±10%) of CₘHₙ prepared according to Example 4
3) Interlayer 2: 150 nm (±10%) of SiOₓC_{y}H_{z}Nₐ prepared according to Example 2

The multi-layer conformal coating had the following structure made up of the above layers:

Base-adhesion layer/(Interlayer 1/Interlayer 2)×3/Interlayer 1/Top layer.

Deposition of the multi-layer conformal coating was performed in a PECVD chamber, conditions described below. An electrical assembly was placed into a PECVD deposition chamber, and the pressure was then brought to ˜10⁻² mbar.

HMDSO and Ar were injected at a flow rate of 17.5 sccm and 20 sccm respectively. Pressure was allowed to stabilize and plasma was ignited at a RF power density of 0.057 Wcm⁻² resulting in a process pressure of 0.140 mbar. The process was run for the time needed to deposit 150 nm (±10%). After this step, the PECVD chamber was brought to vacuum (no gas; vapour injected) and, after having reached ˜10⁻² mbar, p-Xylene was injected at a flow rate of 85 sccm. Pressure was allowed to stabilize and plasma was ignited at RF at a power density of 0.057 Wcm⁻², resulting in a process pressure of 0.048 mbar. The process was run for the time needed to reach 250 nm (±10%). After this step, the PECVD chamber was brought to vacuum (no gas; vapour injected) and, after having reached ˜10⁻² mbar, and HMDSO and N₂O were injected at a flow rate of 17.5 sccm and 30 sccm respectively and pressure was allowed to stabilize. Plasma was ignited at a RF power density of 0.057 Wcm⁻², resulting in a process pressure of 0.160 mbar.

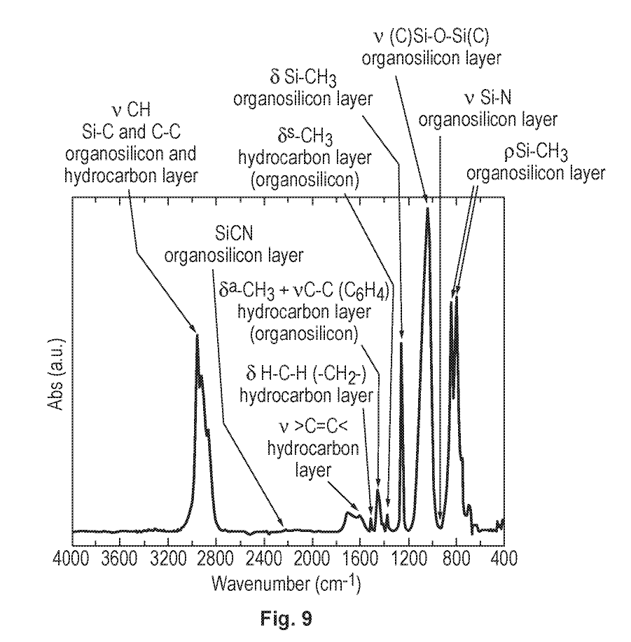

The latter two steps were repeated two times more and then as final step a top layer of SiOₓC_{y}H_{z} was deposited, after evacuating the PECVD chamber to 10⁻² mbar as in Example 1. The FTIR transmission spectrum for the deposited multi-layer is shown in FIG. 9.

1. An electrical assembly which has a multi-layer conformal coating comprising three or more layers on at least one surface of the electrical assembly, wherein:
the lowest layer of the multi-layer conformal coating, which is in contact with the at least one surface of the electrical assembly, is obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr;
the uppermost layer of the multi-layer conformal coating is obtainable by plasma deposition of a precursor mixture comprising (a) one or more organosilicon compounds, (b) optionally O₂, N₂O, NO₂, H₂, NH₃ and/or N₂, and (c) optionally He, Ar and/or Kr; and
the multi-layer coating comprises one or more layers which is obtainable by plasma deposition of a precursor mixture comprising (a) one or more hydrocarbon compounds of formula (A), (b) optionally NH₃, N₂O, N₂, NO₂, CH₄, C₂H₆, C₃H₆ and/or C₃H₈, and (c) optionally He, Ar and/or Kr, 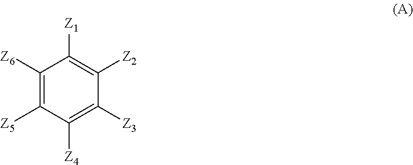
wherein:
Z₁ represents C₁-C₃ alkyl or C₂-C₃ alkenyl;
Z₂ represents hydrogen, C₁-C₃ alkyl or C₂-C₃ alkenyl;
Z₃ represents hydrogen, C₁-C₃ alkyl or C₂-C₃ alkenyl;
Z₄ represents hydrogen, C₁-C₃ alkyl or C₂-C₃ alkenyl;
Z₅ represents hydrogen, C₁-C₃ alkyl or C₂-C₃ alkenyl; and
Z₆ represents hydrogen, C₁-C₃ alkyl or C₂-C₃ alkenyl.

2. The electrical assembly according to claim 1, wherein the multi-layer conformal coating has three to thirteen layers.

3. The electrical assembly according to claim 1 or 2, wherein the plasma deposition is plasma enhanced chemical vapour deposition (PECVD).

4. The electrical assembly according to any one of the preceding claims, wherein the plasma deposition occurs at a pressure of 0.001 to 10 mbar.

5. The electrical assembly according to any one of the preceding claims, wherein the lowest layer of the multi-layer conformal coating is organic.

6. The electrical assembly according to any one of the preceding claims, wherein the lowest layer of the multi-layer conformal coating is obtainable by plasma deposition of a precursor mixture containing no, or substantially no, O₂, N₂O or NO₂.

7. The electrical assembly according to claim 6, wherein the lowest layer of the multi-layer conformal coating is obtainable by plasma deposition of a precursor mixture containing H₂, NH₃, N₂, Ar, He and/or Kr.

8. The electrical assembly according to any one of the preceding claims, wherein the uppermost layer of the multi-layer conformal coating is organic.

9. The electrical assembly according to any one of the preceding claims, wherein the uppermost layer of the multi-layer conformal coating is obtainable by plasma deposition of a precursor mixture comprising He, Ar and/or Kr.

10. The electrical assembly according to any one of the preceding claims, wherein the multi-layer conformal coating has one or more moisture barrier layers obtainable by plasma deposition of a precursor mixture comprising (a) one or more organosilicon compounds, (b) O₂, N₂O and/or NO₂, and (c) optionally He, Ar and/or Kr.

11. The electrical assembly according to any one of the preceding claims, wherein the multi-layer conformal coating has one or more moisture barrier layers obtainable by plasma deposition of a precursor mixture comprising (a) one or more nitrogen-containing organosilicon compounds, (b) N₂, NO₂, N₂O and/or NH₃, and (c) optionally He, Ar and/or Kr.

12. The electrical assembly according to claim 10 or 11, wherein the precursor mixture from which the one or more moisture barrier layers is obtainable further comprises He, Ar and/or Kr.

13. The electrical assembly according to any one of the preceding claims, wherein the one or more organosilicon compounds are independently selected from hexamethyldisiloxane (HMDSO), tetramethyldisiloxane (TMDSO), 1,3-divinyltetramethyldisiloxane (DVTMDSO), hexavinyldisiloxane (HVDSO) allyltrimethylsilane, allyltrimethoxysilane (ATMOS), tetraethylorthosilicate (TEOS), trimethylsilane (TMS), triisopropylsilane (TiPS), trivinyl-trimethyl-cyclotrisiloxane (V₃D₃), tetravinyl-tetramethyl-cyclotetrasiloxane (V₄D₄), tetramethylcyclotetrasiloxane (TMCS), octamethylcyclotetrasiloxane (OMCTS), hexamethyldisilazane (HMDSN), 2,4,6-trimethyl-2,4,6-trivinylcyclotrisilazane, dimethylamino-trimethylsilane (DMATMS), bis(dimethylamino)dimethylsilane (BDMADMS) and tris(dimethylamino)methylsilane (TDMAMS).

14. The electrical assembly according to any one of the preceding claims, wherein the multi-layer coating comprises one, two, three or four layers which are obtainable by plasma deposition of a hydrocarbon compound of formula (A).

15. The electrical assembly according to any one of the preceding claims, wherein the one or more hydrocarbon compounds of formula (A) are selected from 1,4-dimethylbenzene, 1,3-dimethylbenzene, 1,2-dimethylbenzene, toluene, 4-methyl styrene, 3-methyl styrene, 2-methyl styrene, 1,4-divinyl benzene, 1,3-divinyl benzene, 1,2-divinyl benzene, 1,4-ethylvinylbenzene, 1,3-ethylvinylbenzene and 1,2-ethylvinylbenzene.

16. The electrical assembly according to claim 15, wherein the one or more hydrocarbon compounds of formula (A) is 1,4-dimethylbenzene.

17. The electrical assembly according to claim 15, wherein the one or more hydrocarbon compounds of formula (A) is a mixture of 1,4-divinyl benzene, 1,3-divinyl benzene and 1,2-divinyl benzene.

18. The electrical assembly according to any one of the preceding claims, which electrical assembly comprises a substrate comprising an insulating material, a plurality of conductive tracks present on at least one surface of the substrate, and at least one electrical component connected to at least one conductive track.

19. The electrical assembly according to claim 18, wherein the multi-layer conformal coating covers the plurality of conductive tracks, the at least one electrical component and the surface of the substrate on which the plurality of conductive tracks and the at least one electrical component are located.

20. An electrical component which has a multi-layer conformal coating as defined in any one of claims 1 to 19 on at least one surface of the electrical component.

21. The electrical component according to claim 20, which is a resistor, capacitor, transistor, diode, amplifier, relay, transformer, battery, fuse, integrated circuit, switch, LED, LED display, Piezo element, optoelectronic component, antenna or oscillator.
